(19) United States
(12) Patent Application Publication
(10) Pub. No.: US 2005/0005849 A1
(43) Pub. Date: Jan. 13, 2005

(54) Semiconductor processing system

(76) Inventor: Noboru Masuoka, Minami-Alps-shi (JP)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 10/849,062

(22) Filed: May 20, 2004

(30) Foreign Application Priority Data
May 22, 2003 (JP) 2003-145303

(51) Int. Cl. C23C 16/00

(52) U.S. Cl. 118/719

(57) ABSTRACT

A semiconductor processing system includes first and third transfer chambers set to be an atmospheric pressure transfer chamber, and a second transfer chamber set to be a vacuum transfer chamber. The first transfer chamber extends in a first direction, while the second and third transfer chambers extend in a second direction perpendicular to the first direction. The first to third transfer chambers contain first to third transfer mechanisms. A load-port device is connected to the first transfer chamber. The second transfer chamber is connected to the first transfer chamber through a load-lock chamber for pressure adjustment. First vacuum process chambers are arrayed and connected to the second transfer chamber. The third transfer chamber is connected to the first transfer chamber in parallel with the second transfer chamber on a side opposite from the first vacuum process chambers. Processing apparatuses are connected to the third transfer chamber.

### CROSS-REFERENCE TO RELATED APPLICATIONS

This application is based upon and claims the benefit of priority from prior Japanese Patent Application No. 2003-145303, filed May 22, 2003, the entire contents of which are incorporated herein by reference.

### BACKGROUND OF THE INVENTION

1. Field of the Invention

The present invention relates to a semiconductor processing system for performing a predetermined process on a target substrate, such as a semiconductor wafer. The term “semiconductor process” used herein includes various kinds of processes which are performed to manufacture a semiconductor device or a structure having wiring layers, electrodes, and the like to be connected to a semiconductor device, on a substrate, such as a semiconductor wafer or an glass substrate for an LCD (Liquid crystal display) or FPD (Flat Panel Display), by forming semiconductor layers, insulating layers, and conductive layers in predetermined patterns on the substrate.

2. Description of the Related Art

In the process of manufacturing semiconductor devices, a target substrate or semiconductor wafer is subjected to various processes, such as pre-cleaning, film-formation, etching, oxidation, diffusion, annealing, and reformation. Owing to the demands of increased miniaturization and integration of semiconductor devices, the throughput and yield involving these processes need to be increased. In light of this, there is a semiconductor processing system of the so-called multi-chamber type, which has a plurality of process chambers for performing the same process, or a plurality of process chambers for performing different processes, connected to a common transfer chamber. With a system of this type, various steps can be performed in series, without exposing a wafer to air.

Jpn. Pat. Appln. No. 2002-324829 discloses a semiconductor processing system including a vacuum transfer chamber formed of a casing of a polygon, such as hexagon or octagon. In this system, a plurality of vacuum process chambers are disposed around the vacuum transfer chamber and are respectively connected to the sides of the vacuum transfer chamber each through a gate valve. As a consequence, a so-called cluster tool type structure is formed.

Jpn. Pat. Appln. No. 8-119409 discloses a semiconductor processing system including a vacuum transfer chamber formed of an elongated rectangular casing. In this system, a plurality of vacuum process chambers are arrayed along a side of the vacuum transfer chamber and connected to the vacuum transfer chamber each through a gate valve.

U.S. patent application Ser. No. 10/415,993 (Jpn. Pat. Appln. No. 2002-151568), or Jpn. Pat. Appln. No. 2002-134587 discloses a semiconductor processing system including an atmospheric pressure transfer chamber formed of an elongated rectangular casing. In this system, a plurality of processing apparatuses, each having a load-lock chamber and a vacuum process chamber, are arrayed along a side of the atmospheric pressure transfer chamber and connected to the atmospheric pressure transfer chamber each through the load-lock chamber.

### BRIEF SUMMARY OF THE INVENTION

An object of the present invention is to provide a semiconductor processing system that considerably reduces the occupancy area and cost, and improves the throughput.

According to a first aspect of the present invention, there is provided a semiconductor processing system comprising:
a first transfer chamber formed of a casing extending in a first direction and set to be an atmospheric pressure transfer chamber;
a load-port device connected to the first transfer chamber and configured to load and unload a target substrate therethrough;
a first transfer mechanism built in the first transfer chamber and configured to hold and transfer the target substrate, the first transfer mechanism being movable in the first direction within the first transfer chamber, and comprising a transfer arm that handles the target substrate;
a second transfer chamber formed of a casing extending in a second direction perpendicular to the first direction and set to be a vacuum transfer chamber;
a load-lock chamber for pressure adjustment, connecting the first and second transfer chambers to each other and configured to provide a transfer route for the target substrate;
a second transfer mechanism built in the second transfer chamber and configured to hold and transfer the target substrate, the second transfer mechanism being movable in the second direction within the second transfer chamber, and comprising a transfer arm that handles the target substrate;
a plurality of first vacuum process chambers connected to the second transfer chamber and configured to process the target substrate in a vacuum atmosphere, the plurality of first vacuum process chambers being arrayed in the second direction along a sidewall of the second transfer chamber;
a third transfer chamber formed of a casing extending in the second direction and set to be an atmospheric pressure transfer chamber, the third transfer chamber being connected to the first transfer chamber and extending in parallel with the second transfer chamber on a side of the second transfer chamber opposite from the plurality of first vacuum process chambers;
a third transfer mechanism built in the third transfer chamber and configured to hold and transfer the target substrate, the third transfer mechanism being movable in the second direction within the third transfer chamber; and
a plurality of processing apparatuses connected to the third transfer chamber and configured to process the target substrate.

In a second aspect of the present invention, the system according to the first aspect is arranged such that the third transfer mechanism comprises a transfer arm that handles the target substrate. In the second aspect, the system may further comprises a buffer holder disposed at a position where the first transfer chamber is connected to the third transfer chamber, and configured to temporarily place the target substrate thereon between the first and third transfer mechanisms.

In a third aspect of the present invention, the system according to the first aspect further comprises:
a fourth transfer chamber formed of an elongated casing and set to be an atmospheric pressure transfer chamber, the fourth transfer chamber being connected in series to an end of the third transfer chamber opposite from an end thereof connected to the first transfer chamber, and the plurality of processing apparatuses including a processing apparatus connected to the third transfer chamber through the fourth transfer chamber; and
a fourth transfer mechanism built in the fourth transfer chamber and configured to hold and transfer the target substrate, the fourth transfer mechanism being movable in a longitudinal direction of the fourth transfer chamber within the fourth transfer chamber, and comprising a transfer arm that handles the target substrate.

In the third aspect, the third transfer mechanism may comprise a buffer holder configured to temporarily place the target substrate thereon between the first and fourth transfer mechanisms, and may be movable at a speed higher than the first, second, and fourth transfer mechanisms.

In a fourth aspect of the present invention, the system according to the first aspect further comprises:
a fourth transfer chamber formed of a casing extending in the second direction and set to be a vacuum transfer chamber, the fourth transfer chamber being connected to the first transfer chamber and extending in parallel with the third transfer chamber on a side opposite from the second transfer chamber;
a load-lock chamber for pressure adjustment, connecting the first and fourth transfer chambers to each other and configured to provide a transfer route for the target substrate;
a fourth transfer mechanism built in the fourth transfer chamber and configured to hold and transfer the target substrate, the fourth transfer mechanism being movable in the second direction within the fourth transfer chamber, and comprising a transfer arm that handles the target substrate; and
a plurality of second vacuum process chambers connected to the fourth transfer chamber and configured to process the target substrate in a vacuum atmosphere, the plurality of second vacuum process chambers being arrayed in the second direction along a sidewall of the fourth transfer chamber on a side opposite from the third transfer chamber.

Additional objects and advantages of the invention will be set forth in the description which follows, and in part will be obvious from the description, or may be learned by practice of the invention. The objects and advantages of the invention may be realized and obtained by means of the instrumentalities and combinations particularly pointed out hereinafter.

### BRIEF DESCRIPTION OF THE SEVERAL VIEWS OF THE DRAWING

The accompanying drawings, which are incorporated in and constitute a part of the specification, illustrate presently preferred embodiments of the invention, and together with the general description given above and the detailed description of the preferred embodiments given below, serve to explain the principles of the invention.

FIG. 1 is a plan view showing a semiconductor processing system according to a first embodiment of the present invention;

FIG. 2 is a side view showing an alignment mechanism used in the system shown in FIG. 1;

FIG. 3 is a perspective view showing a buffer transfer mechanism used in the system shown in FIG. 1;

FIG. 4 is a plan view showing a semiconductor processing system according to a second embodiment of the present invention;

FIG. 5 is a plan view showing a semiconductor processing system according to a third embodiment of the present invention;

FIG. 6 is a perspective view showing a transit table used in the system shown in FIG. 5;

FIG. 7 is a plan view showing a semiconductor processing system according to a fourth embodiment of the present invention; and

FIG. 8 is a plan view showing a semiconductor processing system according to a fifth embodiment of the present invention.

### DETAILED DESCRIPTION OF THE INVENTION

In the process of developing the present invention, the inventors conducted research on the problems of conventional semiconductor processing systems, such as those described above. As a result, the inventors have arrived at the findings given below.

Semiconductor processing apparatuses have their own priorities, which differ according to the type of the apparatus. For example, for some vacuum processing apparatuses, it is important to transfer a processed wafer to a subsequent process through a vacuum atmosphere. This is intended to prevent a natural oxide film or the like from being formed on the wafer. For other vacuum processing apparatuses, it is more important that the process atmospheres of the apparatuses do not affect each other, than transferring a wafer through a vacuum atmosphere. This is intended to prevent cross contamination between the processing apparatuses.

However, conventional semiconductor processing systems are not designed in consideration of the characters of respective processing apparatuses, and thus they may deteriorate their performance, depending on the combination of processes. Furthermore, systems not designed in consideration of the characters of respective processing apparatuses bring about waste of the functions and spaces of vacuum transfer chambers and load-lock chambers, which are expensive.

For example, the processing system disclosed in Jpn. Pat. Appln. No. 2002-324829 includes a hexagonal or octagonal vacuum transfer chamber with process chambers connected to its side, to arrange a cluster tool type structure. In this case, a considerable number of useless spaces are formed between the process chambers, and increase the occupancy area of the processing system. Particularly, where a plurality of vacuum transfer chambers are connected, the transfer mechanism that transfers wafers to and from the outside of the processing system can fall into a busy state. As a consequence, wafers occasionally have to wait for transfer, which lowers the throughput.

The processing system disclosed in Jpn. Pat. Appln. No. 8-119409 includes an elongated rectangular vacuum transfer chamber. In this case, the volume of the transfer chamber needs to be larger, as compared to a hexagonal or octagonal transfer chamber, for arrangement of the same number of process chambers. Since the cost per unit volume of vacuum transfer chambers is high, this processing system renders a low cost performance.

The processing system disclosed in U.S. patent application Ser. No. 10/0,415,993 (Jpn. Pat. Appln. No. 2002-151568), or Jpn. Pat. Appln. No. 2002-134587 includes an elongated rectangular atmospheric pressure transfer chamber. In this case, since the cost of atmospheric pressure transfer chambers is lower than vacuum transfer chambers, this system is preferable in terms of the cost. However, when a wafer is transferred between two process chambers, the wafer has to pass through an atmospheric pressure atmosphere.

Embodiments of the present invention achieved on the basis of the findings given above will now be described with reference to the accompanying drawings. In the following description, the constituent elements having substantially the same function and arrangement are denoted by the same reference numerals, and a repetitive description will be made only when necessary.

<First Embodiment>

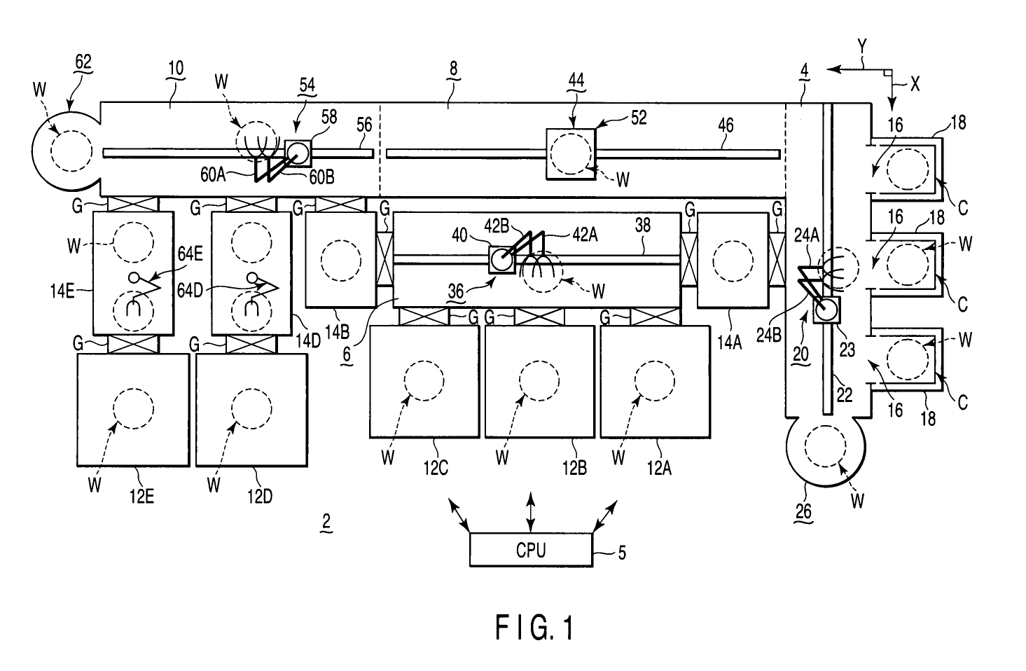

FIG. 1 is a plan view showing a semiconductor processing system according to a first embodiment of the present invention. This processing system 2 is arranged to process a semiconductor wafer as a target substrate. A CPU 5 is arranged to control operations of the respective portions of the processing system 2 (for example, an operation for performing a process method or transfer method, described later) in accordance with a program preset therein.

As shown in FIG. 1, this processing system 2 includes a first atmospheric pressure transfer chamber 4, a first vacuum transfer chamber 6, an atmospheric pressure buffer transfer chamber 8, and a second atmospheric pressure transfer chamber 10. Each of the transfer chambers 4, 6, 8, and 10 is formed of an elongated rectangular casing made of, e.g., stainless steel. The first atmospheric pressure transfer chamber 4 is disposed to extend in an X direction (first direction), while the first vacuum transfer chamber 6, atmospheric pressure buffer transfer chamber 8, and second atmospheric pressure transfer chamber 10 are disposed to extend in a Y direction (second direction) perpendicular to the X direction.

The interior of the first atmospheric pressure transfer chamber 4 is set to have an atmosphere of atmospheric pressure or positive pressure, formed by clean air or an inactive gas, such as N₂ gas. The first atmospheric pressure transfer chamber 4, which extends in the X direction, has one longitudinal sidewall provided with a plurality of, e.g., three in this example, transfer ports 16 formed therein. The transfer ports 16 are respectively connected to load-port devices 18. Each of the load-port devices 18 is configured to accommodate a cassette C that can store a plurality of, e.g., 25, semiconductor wafers W.

The first atmospheric pressure transfer chamber 4 contains a first transfer mechanism 20, which is movable in the X direction, to hold and transfer a wafer W. The first transfer mechanism 20 includes a guide rail 22 disposed to extend in the longitudinal direction of the first atmospheric pressure transfer chamber 4. A base 23 is attached to the guide rail 22 and arranged to travel along the guide rail 22 by, e.g., a linear motor mechanism.

The base 23 is provided with a plurality of, e.g., two, articulated arms 24A and 24B each of which is extensible/contractible to handle a wafer W. The articulated arms 24A and 24B are also movable in the vertical direction and angular direction. The first transfer mechanism 20 holds and transfers a wafer or wafers W by arms 24A and 24B. The arms 24A and 24B are not limited to an articulated arm. They may be three or more in number. These modifications are also applied to the other transfer mechanisms described later.

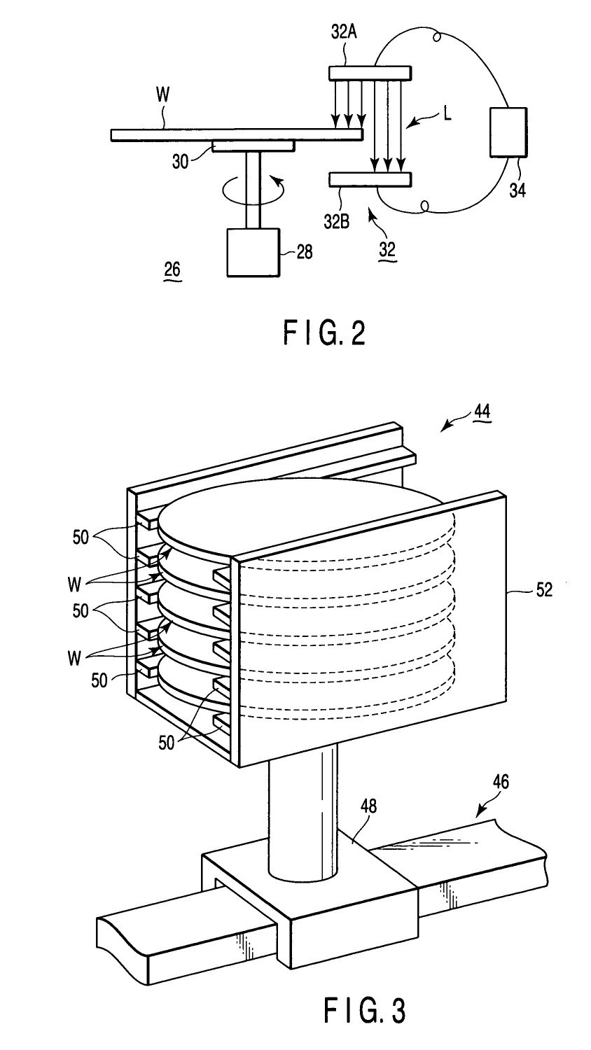

A first alignment mechanism or first orientor 26 is disposed at an end of the first atmospheric pressure transfer chamber 4, to perform alignment of a wafer W. FIG. 2 is a side view showing a first orientor 26. As shown in FIG. 2, the first orientor 26 includes a reference table 30, which is rotated by a drive motor 28. The reference table 30 is rotated along with the wafer W placed thereon.

A sensor, such as an optical sensor 32, is disposed around the reference table 30, to detect the peripheral edge of the wafer W. The optical sensor 32 includes a linear light-emitting element 32A and a light-receiving element 32B. The linear light-emitting element 32A has a predetermined length and extends in the radial direction of the reference table 30. The light-receiving element 32B is disposed to face the linear light-emitting element 32A with the wafer peripheral edge interposed therebetween. The optical sensor 32 radiates a curtain leaser beam L onto the wafer edge to detect changes therein.

Signals detected by the optical sensor 32 are transmitted to a calculation/detection section 34. Based on the detected signals, the calculation/detection section 34 calculates the misalignment amount and misalignment direction of the wafer W, and the position of a cutout mark of the wafer W, such as a notch or orientation flat, i.e., the orientation of the wafer W.

The interior of the first vacuum transfer chamber 6 is set to have a vacuum atmosphere of, e.g., about 10 to 100 Pa. The first vacuum transfer chamber 6, which extends in the Y direction, is connected to the other longitudinal sidewall of the first atmospheric pressure transfer chamber 4 through a load-lock chamber 14A that provides a transfer route for a wafer W. The two sides of the load-lock chamber 14A which are connected to the transfer chambers 4 and 6 are respectively provided with gate valves G. An inactive gas supply section and a vacuum-exhaust section are connected to the load-lock chamber 14A, so that the pressure inside the chamber 14A can be swiftly adjusted between vacuum and atmospheric pressure. All of the load-lock chambers described hereinafter have the same pressure adjustment function as the load-lock chamber 14A. The inside of the load-lock chamber 14A is structured to place at least one wafer W.

The first vacuum transfer chamber 6 contains a second transfer mechanism 36, which is movable in the Y direction, to hold and transfer a wafer W. The second transfer mechanism 36 includes a guide rail 38 disposed to extend in the longitudinal direction of the first vacuum transfer chamber 6. A base 40 is attached to the guide rail 38 and arranged to travel along the guide rail 38 by, e.g., a linear motor mechanism.

The base 40 is provided with a plurality of, e.g., two, articulated arms 42A and 42B each of which is extensible/contractible to handle a wafer W. The articulated arms 42A and 42B are also movable in the vertical direction and angular direction. The second transfer mechanism 36 holds and transfers a wafer or wafers W by arms 42A and 42B.

A plurality of, three in this example, vacuum process chambers 12A to 12C are arrayed in the Y direction along one longitudinal sidewall of the first vacuum transfer chamber 6. The vacuum process chambers 12A to 12C are connected to the first vacuum transfer chamber 6 respectively through gate valves G.

Each of the vacuum process chambers 12A to 12C is arranged to process a wafer W in a vacuum atmosphere. The processes performed in the vacuum process chambers 12A to 12C include vacuum processes that should be successively performed without exposing a wafer W to atmospheric air even during transfer. However, they include a vacuum process that does not cause a problem even if the processed wafer W is exposed to atmospheric air, so that it is performed immediately before the wafer W is transferred out of the first vacuum transfer chamber 6. The vacuum process chambers 12A to 12C are designed to combine such vacuum processes.

The atmospheric pressure buffer transfer chamber 8, which extends in the Y direction, is connected to the other longitudinal sidewall of the first atmospheric pressure transfer chamber 4, to form an inner space continuous to that of the first atmospheric pressure transfer chamber 4. Accordingly, the interior of the atmospheric pressure buffer transfer chamber 8 has an atmosphere common to that of the first atmospheric pressure transfer chamber 4. In other words, it is set to have an atmosphere of atmospheric pressure or positive pressure, formed by clean air or an inactive gas, such as N₂ gas. The atmospheric pressure buffer transfer chamber 8 extends in parallel with the first vacuum transfer chamber 6, on the side opposite from the vacuum process chambers 12A to 12C with the first vacuum transfer chamber 6 interposed therebetween.

The atmospheric pressure buffer transfer chamber 8 contains a buffer transfer mechanism 44, which is movable in the Y direction, to hold and transfer wafers W. FIG. 3 is a perspective view showing the buffer transfer mechanism 44. As shown in FIG. 3, the buffer transfer mechanism 44 includes a guide rail 46 disposed to extend in the longitudinal direction of the atmospheric pressure buffer transfer chamber 8. A base 48 is attached to the guide rail 46 and arranged to travel along the guide rail 46 by, e.g., a linear motor mechanism.

The base 48 is provided with a wafer holder 52 fixed thereon, which has a plurality of wafer support shelves 50 forming, e.g., five levels in FIG. 3 to place wafers W thereon. The buffer transfer mechanism 44 can transfer five wafers W at most, while supporting the wafers W on the wafer support shelves 50. The buffer transfer mechanism 44 can travel along the guide rail at a speed higher than the other transfer mechanisms having articulated arms, such as the first transfer mechanism 20.

The second atmospheric pressure transfer chamber 10, which extends in the Y direction, is connected in series to the opposite end of the atmospheric pressure buffer transfer chamber 8 from the end thereof connected to the first atmospheric pressure transfer chamber 4, to form an inner space continuous to that of the atmospheric pressure buffer transfer chamber 8. Accordingly, the interior of the second atmospheric pressure transfer chamber 10 has an atmosphere common to those of the first atmospheric pressure transfer chamber 4 and the atmospheric pressure buffer transfer chamber 8. In other words, it is set to have an atmosphere of atmospheric pressure or positive pressure, formed by clean air or an inactive gas, such as N₂ gas.

The second atmospheric pressure transfer chamber 10 contains a third transfer mechanism 54, which is movable in the Y direction, to hold and transfer a wafer W. The third transfer mechanism 54 includes a guide rail 56 disposed to extend in the longitudinal direction of the second atmospheric pressure transfer chamber 10. A base 58 is attached to the guide rail 56 and arranged to travel along the guide rail 56 by, e.g., a linear motor mechanism.

The base 58 is provided with a plurality of, e.g., two, articulated arms 60A and 60B each of which is extensible/contractible to handle a wafer W. The articulated arms 60A and 60B are also movable in the vertical direction and angular direction. The third transfer mechanism 54 holds and transfers a wafer or wafers W by arms 60A and 60B.

A second alignment mechanism or second orientor 62 is disposed at an end of the second atmospheric pressure transfer chamber 10, to perform alignment of a wafer W. The second orientor 62 has the same structure as the first orientor 26, as shown in FIG. 2.

A plurality of, e.g., two in this example, vacuum process chambers 12D and 12E are arrayed in the Y direction along one longitudinal sidewall of the second atmospheric pressure transfer chamber 10. They are arrayed next to the first vacuum transfer chamber 6 or vacuum process chambers 12A to 12C in the Y direction. The vacuum process chambers 12D and 12E are connected to the second atmospheric pressure transfer chamber 10 respectively through load-lock chambers 14D and 14E for pressure adjustment. The two sides of each of the load-lock chambers 14D and 14E which are connected to the transfer chamber 10 and process chamber 12D or 12E are respectively provided with gate valves G.

Each of the vacuum process chambers 14D and 14E is arranged to process a wafer W in a vacuum atmosphere. For example, the vacuum process chambers 12D and 12E are arranged to perform processes that do not cause a problem even if a wafer W is exposed to atmospheric air before or after the process. The vacuum process chambers 12D and 12E are arranged to perform processes for which it is more important that the process atmospheres of the apparatuses do not affect each other, than transferring a wafer through a vacuum atmosphere.

Each of the load-lock chambers 14D and 14E has a length larger than the load-lock chamber 14A and contains two supports disposed at front and rear sides to place two wafers at one time (they are shown as the positions of wafers W in FIG. 1). A transfer arm 64D or 64E, which is extensible/contractible and rotatable, is disposed between the wafer supports. The transfer arm 64D or 64E transfers a wafer W between the load-lock chamber 14D or 14E and the vacuum process chamber 12D or 12E.

The second atmospheric pressure transfer chamber 10 is connected to the first vacuum transfer chamber 6 through a load-lock chamber 14B that provides a transfer route for a wafer W. The two sides forming an angle of 90 degrees of the load-lock chamber 14B which are connected to the transfer chambers 6 and 10 are respectively provided with gate valves G. The inside of the load-lock chamber 14B is structured to place at least one wafer W.

Next, an explanation will be given of a process method and transfer method, performed in the semiconductor processing system 2.

An unprocessed semiconductor wafer W is picked up by the first transfer mechanism 20 from a cassette C placed in one of the load-port devices 18 connected to the first atmospheric pressure transfer chamber 4, and is taken into the processing system 2. The wafer W thus picked up is subjected to a predetermined series of processes, and, after the processes on the wafer W are completed, the wafer W is returned into the cassette C.

<Where a Wafer is First Processed in the Vacuum Process Chambers 12A to 12C>

Where a wafer W taken into the processing system 2 is first processed in the vacuum process chambers 12A to 12C, the wafer W is transferred in the following order: First orientor 26→load-lock chamber 14A→first vacuum transfer chamber 6→vacuum process chambers 12A to 12C→load-lock chamber 14B→second atmospheric pressure transfer chamber 10→load-lock chambers 14D and 14E→vacuum process chambers 12D and 12E→second atmospheric pressure transfer chamber 10→atmospheric pressure buffer transfer chamber 8→first atmospheric pressure transfer chamber 4.

Where a series of processes starts from one of the vacuum process chambers 12A to 12C connected to the first vacuum transfer chamber 6, the processes proceed as follows. Specifically, an unprocessed wafer W is transferred by the first transfer mechanism 20 from one of the load-port devices 18 to the first orientor 26. The wafer is subjected to alignment in the first orientor 26. The aligned wafer W is transferred by the first transfer mechanism 20 into the load-lock chamber 14A. The wafer W is then taken by the second transfer mechanism 36 from the load-lock chamber 14A into the first vacuum transfer chamber 6. As well known, when the load-lock chamber 14A is opened and closed, pressure adjustment is always performed to prevent the vacuum chamber from suffering vacuum break. This matter is common to all the other load-lock chambers.

The wafer W thus taken into the first vacuum transfer chamber 6 is transferred among the vacuum process chambers 12A to 12C to receive a series of processes, as needed. The successive transfer of the wafer W among the vacuum process chambers 12A to 12C is performed by the second transfer mechanism 36 in a vacuum atmosphere without exposing the wafer W to an atmospheric pressure atmosphere. Depending on the type of the vacuum process chambers 12A to 12C, a series of processes is not necessarily performed using all the vacuum process chambers 12A to 12C, but is performed using at least two of the vacuum process chambers. In any case, the last one of two or three processes is a process that does not cause a problem even if the wafer W is exposed to atmospheric air after the process.

The wafer W that has thus received a series of necessary processes in the vacuum process chambers 12A to 12C is transferred by the second transfer mechanism 36 into the load-lock chamber 14B disposed at the other end of the first vacuum transfer chamber 6. The wafer W is then taken by the third transfer mechanism 54 from the load-lock chamber 14B into the second atmospheric pressure transfer chamber 10. In this case, the wafer W may be transferred to the second atmospheric pressure transfer chamber 10 through the other load-lock chamber 14A, first atmospheric pressure transfer chamber 4, and atmospheric pressure buffer transfer chamber 8. However, this route is not preferable because it is very long and increases the transfer time, thereby lowing the throughput.

The wafer W thus taken into the second atmospheric pressure transfer chamber 10 is transferred by the third transfer mechanism 54 into one of the load-lock chambers 14D and 14E connected to the second atmospheric pressure transfer chamber 10. After pressure adjustment of the load-lock chamber, the wafer W is transferred by the transfer arm 64D or 64E from the load-lock chamber 14D or 14E into the vacuum process chamber 12D or 12E. The wafer is subjected to a predetermined process in the vacuum process chamber 12D or 12E. The processed wafer W is returned to the second atmospheric pressure transfer chamber 10 via a route reverse to that described above. In this case, a series of processes may be performed using the two vacuum process chambers 12D and 12E, or only one process may be performed using one of the vacuum process chambers.

The wafer W that has thus received a process or processes in the vacuum process chambers 12D and 12E is transferred by the third transfer mechanism 54 into the wafer holder 52 (see FIG. 3) of the buffer transfer mechanism 44 built in the atmospheric pressure buffer transfer chamber 8. As shown in FIG. 3, the buffer transfer mechanism 44 can hold five wafers W at most. Accordingly, the buffer transfer mechanism 44 travels toward the first atmospheric pressure transfer chamber 4, after a certain number of processed wafers W are placed thereon. Since the wafers W have already received all the processes, no problem arises by positional shift of the wafers W within a certain permissible range during this travel. This allows the buffer transfer mechanism 44 to travel at a high speed, thereby improving the throughput by that much.

When the buffer transfer mechanism 44 arrives at the end connected to the first atmospheric pressure transfer chamber 4 (the right end in FIG. 1), the buffer transfer mechanism 44 stays at this position. Each of the processed wafers W held on the buffer transfer mechanism 44 is transferred by the first transfer mechanism 20, built in the first atmospheric pressure transfer chamber 4, into a predetermined cassette C placed in one of the load-port devices 18.

<Where a Wafer is First Processed in the Vacuum Process Chambers 12D and 12E>

Where a wafer W taken into the processing system 2 is first processed in the vacuum process chambers 12D and 12E, the wafer W is transferred in the following order: Atmospheric pressure buffer transfer chamber 8→second atmospheric pressure transfer chamber 10→second orientor 62→load-lock chambers 14D and 14E→vacuum process chambers 12D and 12E→second atmospheric pressure transfer chamber 10→load-lock chamber 14B→first vacuum transfer chamber 6→vacuum process chambers 12A to 12C→load-lock chamber 14A→first atmospheric pressure transfer chamber 4.

Where processes start from one of the vacuum process chambers 12D and 12E connected to the second atmospheric pressure transfer chamber 10, the processes proceed as follows. Specifically, an unprocessed wafer W is transferred by the first transfer mechanism 20 from one of the load-port devices 18 into the wafer holder 52 (see FIG. 3) of the buffer transfer mechanism 44. At this time, the buffer transfer mechanism 44 stays at that end of the atmospheric pressure buffer transfer chamber 8 which is connected to the first atmospheric pressure transfer chamber 4.

As shown in FIG. 3, the buffer transfer mechanism 44 can hold five wafers W at most. Accordingly, the buffer transfer mechanism 44 travels toward the second atmospheric pressure transfer chamber 10, after a certain number of unprocessed wafers W are placed thereon. Since the wafers W are subjected to alignment afterward, no problem arises by positional shift of the wafers W within a certain permissible range during this travel. This allows the buffer transfer mechanism 44 to travel at a high speed, thereby improving the throughput by that much.

When the buffer transfer mechanism 44 arrives at the end connected to the second atmospheric pressure transfer chamber 10 (the left end in FIG. 1), the buffer transfer mechanism 44 stays at this position. Each of the unprocessed wafers W held on the buffer transfer mechanism 44 is transferred by the third transfer mechanism 54 to the second orientor 62. The wafer is subjected to alignment in the second orientor 62. The aligned wafer W is transferred by the third transfer mechanism 54 into one of the load-lock chambers 14D and 14E. After pressure adjustment of the load-lock chamber, the wafer W is transferred by the transfer arm 64D or 64E from the load-lock chamber 14D or 14E into the vacuum process chamber 12D or 12E. The wafer is subjected to a predetermined process in the vacuum process chamber 12D or 12E.

The processed wafer W is returned to the second atmospheric pressure transfer chamber 10 via a route reverse to that described above. In this case, a series of processes may be performed using the two vacuum process chambers 12D and 12E, or only one process may be performed using one of the vacuum process chambers.

The wafer W that has thus received a process or processes in the vacuum process chambers 12D and 12E is transferred by the third transfer mechanism 54 into the load-lock chamber 14B. The wafer W is then taken by the second transfer mechanism 36 from the load-lock chamber 14B into the first vacuum transfer chamber 6. In this case, the wafer W may be transferred to the first vacuum transfer chamber 6 through the atmospheric pressure buffer transfer chamber 8, first atmospheric pressure transfer chamber 4, and load-lock chamber 14A. However, this route is not preferable because it is very long and increases the transfer time, thereby lowing the throughput.

The wafer W thus taken into the first vacuum transfer chamber 6 is transferred among the vacuum process chambers 12A to 12C to receive a series of processes, as needed. The successive transfer of the wafer W among the vacuum process chambers 12A to 12C is performed by the second transfer mechanism 36 in a vacuum atmosphere without exposing the wafer W to an atmospheric pressure atmosphere. Depending on the type of the vacuum process chambers 12A to 12C, a series of processes is not necessarily performed using all the vacuum process chambers 12A to 12C, but is performed using at least two of the vacuum process chambers. In any case, the last one of two or three processes is a process that does not cause a problem even if the wafer W is exposed to atmospheric air after the process.

The wafer W that has thus received a series of necessary processes in the vacuum process chambers 12A to 12C is transferred into the load-lock chamber 14A disposed at the end of the first vacuum transfer chamber 6. The wafer W is then taken by the first transfer mechanism 20 from the load-lock chamber 14A into the first atmospheric pressure transfer chamber 4, and returned into a predetermined cassette C placed in one of the load-port devices 18.

Accordingly to the semiconductor processing system shown in FIG. 1, the first vacuum transfer chamber 6 entailing a high installation cost is set to have a small size, e.g., length, thereby reducing the cost of the system. The arrangement of the processing system hardly wastes space, thereby reducing the occupancy area. Although the three vacuum process chambers 12A to 12C are connected to the first vacuum transfer chamber 6, the number of vacuum process chambers disposed here can be any number falling in a range of two or more. Also, the number of vacuum process chambers connected to the second atmospheric pressure transfer chamber 10 can be any number falling in a range of one or more.

The second atmospheric pressure transfer chamber 10 may be connected to the end of the atmospheric pressure buffer transfer chamber 8 to extend not in the Y direction but in the X direction, i.e., perpendicular to the atmospheric pressure buffer transfer chamber 8 (downward in FIG. 1). In this case, the second atmospheric pressure transfer chamber 10 is disposed parallel with and symmetric with the first atmospheric pressure transfer chamber 4, with the first vacuum transfer chamber 6 interposed therebetween. The vacuum process chambers 12D and 12E are then preferably connected to the outer sidewall of the second atmospheric pressure transfer chamber 10 opposite from the first vacuum transfer chamber 6.

The contents of the vacuum process chambers 12A to 12E may be arranged as follows. For example, the vacuum process chamber 12A performs a cleaning process for removing a natural oxide film on the surface of a wafer. The vacuum process chamber 12B performs a CVD process for forming a Ti film on the wafer after the cleaning process. The vacuum process chamber 12C performs a CVD process for forming a TiN film on the Ti film. The vacuum process chambers 12D and 12E perform a CVD process for forming a W (tungsten) film on the TiN film. In this case, the wafer W is transferred in the following order: The vacuum process chamber 12A→vacuum process chamber 12B→vacuum process chamber 12C→vacuum process chamber 12D or vacuum process chamber 12E.

<Second Embodiment>

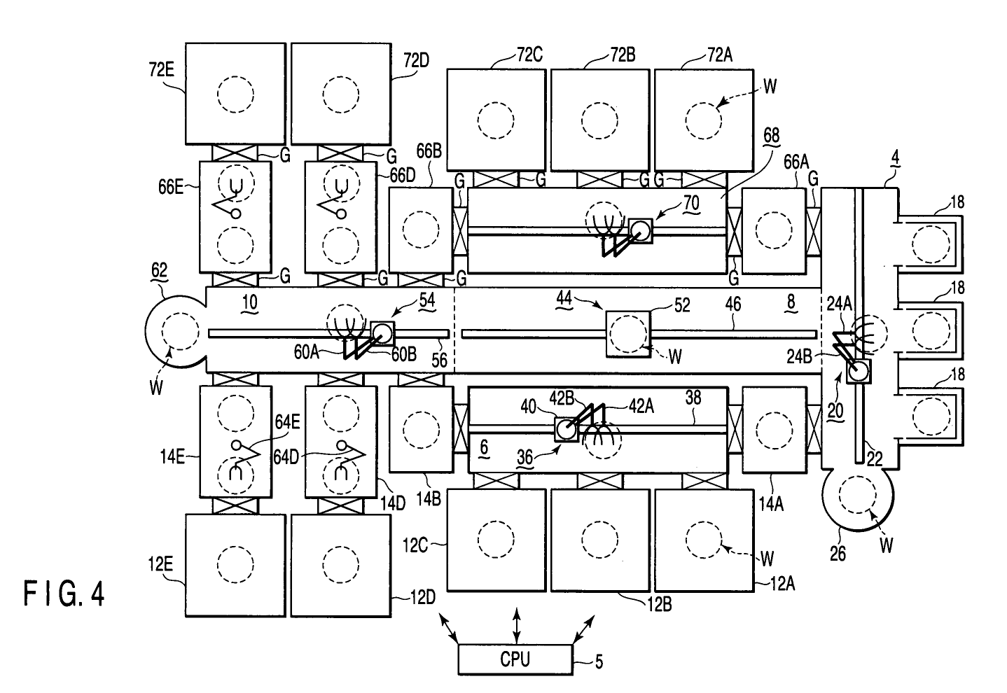

FIG. 4 is a plan view showing a semiconductor processing system according to a second embodiment of the present invention. The processing system shown in FIG. 1 does not utilize a space on the opposite side (on the upper side in FIG. 1) from the first vacuum transfer chamber 6, with the atmospheric pressure buffer transfer chamber 8 and second atmospheric pressure transfer chamber 10 interposed therebetween. The processing system shown in FIG. 4 utilizes this space on the opposite side. This processing system is also arranged to process a semiconductor wafer as a target substrate. A CPU 5 is arranged to control operations of the respective portions of the processing system in accordance with a program preset therein.

As shown in FIG. 4, in this processing system, the atmospheric pressure buffer transfer chamber 8 is connected to the first atmospheric pressure transfer chamber 4 at a position near the center in the longitudinal direction of the chamber 4. The same members as the first vacuum transfer chamber 6 and vacuum process chambers 12A to 12E shown in FIG. 1 are disposed in a space on the opposite side (on the upper side in FIG. 4) from the first vacuum transfer chamber 6, with the atmospheric pressure buffer transfer chamber 8 and second atmospheric pressure transfer chamber 10 interposed therebetween. In other words, the vacuum transfer chambers and vacuum process chambers are disposed symmetric on both sides (on the upper and lower sides in FIG. 4) of the atmospheric pressure buffer transfer chamber 8 and second atmospheric pressure transfer chamber 10, which are at the center of symmetry.

More specifically, a load-lock chamber 66A, a second vacuum transfer chamber 68, and three vacuum process chambers 72A, 72B, and 72C are disposed symmetric with the load-lock chamber 14A, first vacuum transfer chamber 6, and vacuum process chambers 12A to 12E, using the atmospheric pressure buffer transfer chamber 8 as the line-symmetric center. The second vacuum transfer chamber 68 contains a fourth transfer mechanism 70 having the same structure as the second transfer mechanism 36. The vacuum process chambers 72A, 72B, and 72C are arranged to perform processes, e.g., the same as those of the three vacuum process chambers 12A to 12C, as described above.

Furthermore, load-lock chambers 66B, 66D, and 66E and vacuum process chambers 72D and 72E are disposed symmetric with the load-lock chambers 14B, 14D, and 14E and vacuum process chambers 12D and 12E, using the second atmospheric pressure transfer chamber 10 as the line-symmetric center. The vacuum process chambers 72D and 72E are arranged to perform processes, e.g., the same as those of the two vacuum process chambers 12D and 12E, as described above.

As a consequence, the atmospheric pressure buffer transfer chamber 8 is interposed between and parallel with the first and second vacuum transfer chambers 6 and 68.

The processing system shown in FIG. 4 can operate in the same manner as the processing system show in FIG. 1, thereby exhibiting the same effect. In this case, however, since the vacuum process chambers are disposed on both sides of the atmospheric pressure buffer transfer chamber 8 and second atmospheric pressure transfer chamber 10, the buffer transfer mechanism 44, third transfer mechanism 54, and first transfer mechanism 20 are busier in operation by that much as an increase in the number of process chambers.

The vacuum process chambers 72A to 72C are not necessarily arranged to perform the same processes as those of the vacuum process chambers 12A to 12C. Typically, as described previously, the vacuum process chambers 72A to 72C are arranged to perform processes that should be successively performed without exposing a wafer W to atmospheric air even during transfer.

Similarly, the vacuum process chambers 72D and 72E are not necessarily arranged to perform processes the same as those of the vacuum process chambers 12D and 12E. Typically, as described previously, the vacuum process chambers 72D and 72E are arranged to perform processes that do not cause a problem even if a wafer W is exposed to atmospheric air before or after the process. Alternately, the vacuum process chambers 72D and 72E are arranged to perform processes for which it is more important that the process atmospheres of the apparatuses do not affect each other, than transferring a wafer through a vacuum atmosphere.

<Third Embodiment>

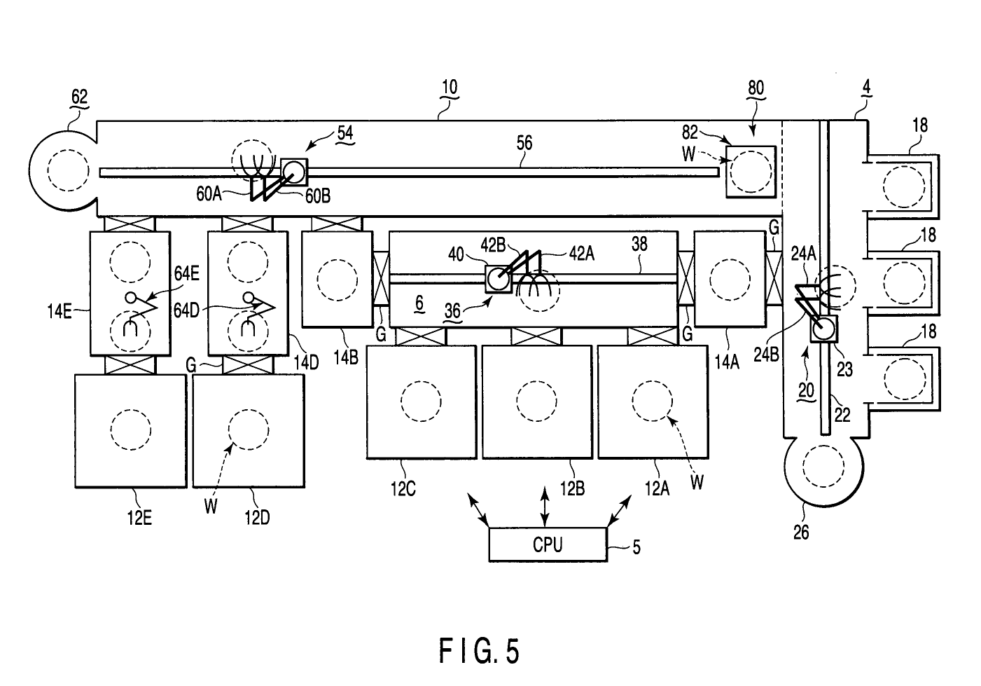

FIG. 5 is a plan view showing a semiconductor processing system according to a third embodiment of the present invention. The processing system shown in FIG. 1 includes the atmospheric pressure buffer transfer chamber 8 and buffer transfer mechanism 44 to obtain a high speed transfer of wafers W and a transfer buffer function, between the second atmospheric pressure transfer chamber 10 and first atmospheric pressure transfer chamber 4. In place of the atmospheric pressure buffer transfer chamber 8 and second atmospheric pressure transfer chamber 10 shown in FIG. 1, the processing system shown in FIG. 5 employs one longer second atmospheric pressure transfer chamber. This processing system is also arranged to process a semiconductor wafer as a target substrate. A CPU 5 is arranged to control operations of the respective portions of the processing system in accordance with a program preset therein.

As shown in FIG. 5, this processing system includes a second atmospheric pressure transfer chamber 10 and a guide rail 56 longer than those shown in FIG. 1. The second atmospheric pressure transfer chamber 10 is directly connected to a sidewall of the first atmospheric pressure transfer chamber 4. A transit table (buffer table) 80 for temporarily holding wafers W is disposed in the second atmospheric pressure transfer chamber 10 on the side connected to the first atmospheric pressure transfer chamber. The transit table 80 provides a buffer function in transfer of wafers W.

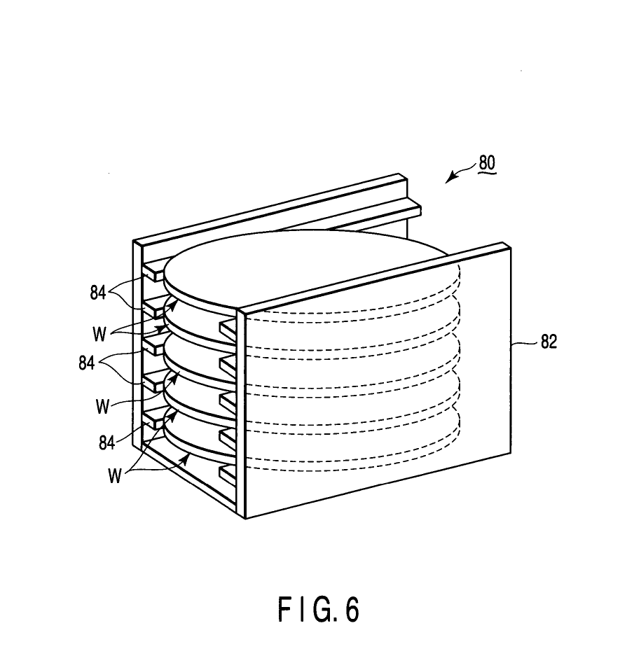

FIG. 6 is a perspective view showing a transit table 80. As shown in FIG. 6, the transit table 80 is provided with a wafer holder 82, which has a plurality of wafer support shelves 84 forming, e.g., five levels in FIG. 6 to place wafers W thereon. The transit table 80 is stationary in the second atmospheric pressure transfer chamber 10, but it can support five wafers W at most on the wafer support shelves 84.

In other words, the transit table 80 has the same structure as the upper part of the buffer transfer mechanism 44 shown in FIG. 3, and has the same function as the buffer transfer mechanism 44 except that it is stationary. The transit table 80 temporarily supports wafers W, thereby allowing transfer of the wafers W to be flexible between the first and third transfer mechanisms 20 and 54. The transit table 80 may be omitted to directly transfer wafers W between the first and third transfer mechanisms 20 and 54.

Since the processing system shown in FIG. 5 has no atmospheric pressure buffer transfer chamber 8, it takes longer to transfer wafers W by that much, thereby lowering the throughput. Apart from this, the processing system shown in FIG. 5 can exhibit the same operation and effect as the processing system show in FIG. 1.

<Fourth Embodiment>

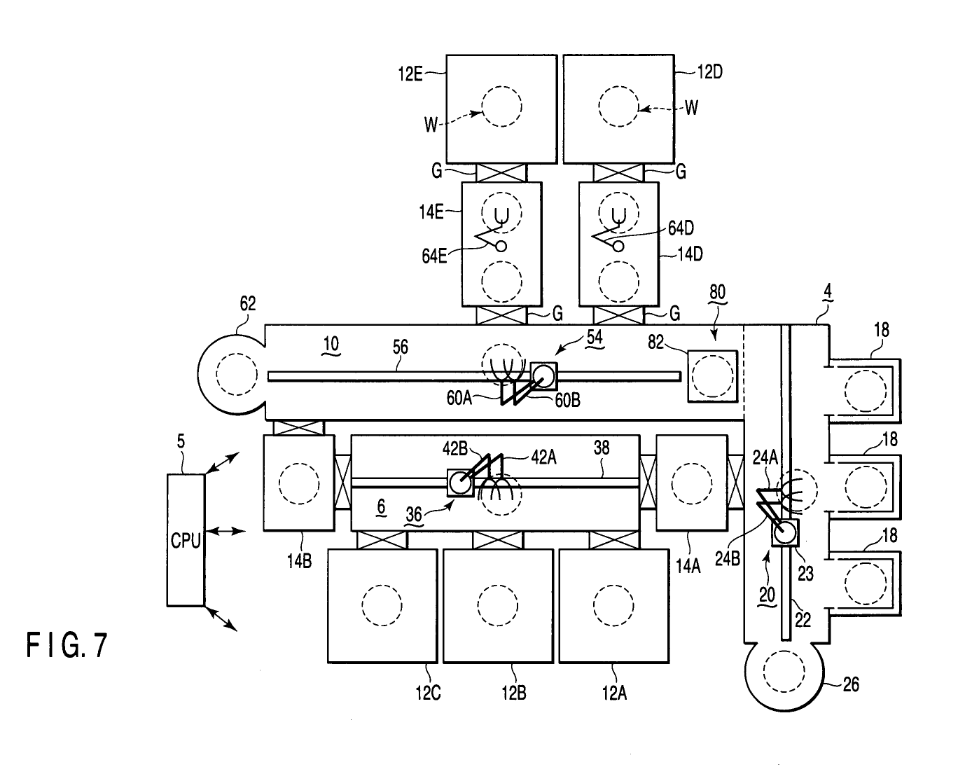

FIG. 7 is a plan view showing a semiconductor processing system according to a fourth embodiment of the present invention. The processing system shown in FIG. 7 includes a second atmospheric pressure transfer chamber 10 and a guide rail 56 shorter than those shown in FIG. 5. The vacuum process chambers 12D and 12E with two load-lock chambers 14D and 14E are connected to a sidewall of the second atmospheric pressure transfer chamber 10 opposite from the first vacuum transfer chamber 6, with the second atmospheric pressure transfer chamber 10 interposed therebetween. The vacuum process chambers 12D and 12E are disposed closer to the first atmospheric pressure transfer chamber 4.

As described above, the processing system shown in FIG. 7 includes the second atmospheric pressure transfer chamber 10 far shorter than that of the processing system shown in FIG. 5. This increases the transfer efficiency of wafers W, thereby improving the throughput. As compared to the processing system shown in FIG. 5, the processing system shown in FIG. 7 reduces the occupancy area in the length direction (the horizontal direction in FIG. 7) and increases the occupancy area in the width direction (the vertical direction in FIG. 7). Accordingly, the processing systems shown in FIGS. 5 and 7 may be selectively used, depending on the location for installing the processing system. Otherwise, the processing system shown in FIG. 7 can exhibit the same operation and effect as the processing system show in FIG. 5.

<Fifth Embodiment>

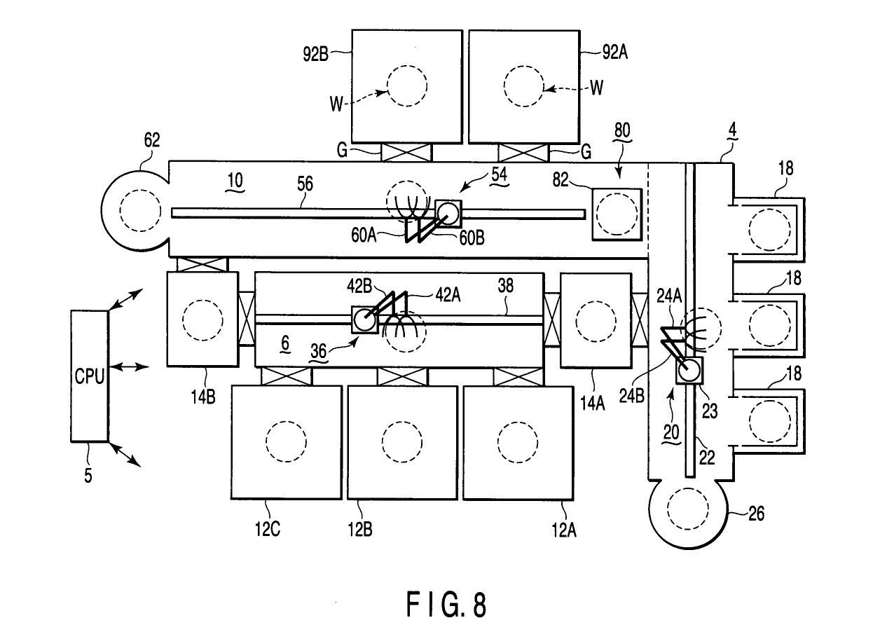

FIG. 8 is a plan view showing a semiconductor processing system according to a fifth embodiment of the present invention. In place of the vacuum process chambers 12D and 12E described above, the processing system shown in FIG. 8 includes atmospheric pressure process chambers 92A and 92B connected to the second atmospheric pressure transfer chamber 10 respectively through gate valve G. Each of the atmospheric pressure process chambers 92A and 92B is arranged to perform a process on a wafer W in an atmospheric pressure atmosphere, such as cleaning, drying, heating, or cooling. The processing system shown in FIG. 8 can perform a process sequence formed of an arbitrary combination of vacuum processes and atmospheric pressure processes.

The atmospheric pressure process chambers 92A and 92B may be connected to the second atmospheric pressure transfer chamber 10, in addition to the vacuum process chambers 12D and 12E in the processing system shown in FIG. 5 or 7. In this case, for the processing system shown in FIG. 5, the atmospheric pressure process chambers 92A and 92B can be disposed on the opposite side from the vacuum process chambers 12D and 12E, with the second atmospheric pressure transfer chamber 10 interposed therebetween. For the processing system shown in FIG. 7, the atmospheric pressure process chambers 92A and 92B can be disposed on the same side as the vacuum process chambers 12D and 12E and arrayed along with them.

In the first to fifth embodiments, the first and second vacuum transfer chambers 6 and 68 respectively contain the second and fourth transfer mechanisms 36 and 70, which utilize a linear motor mechanism. Alternately, for example, the base 40 (see FIG. 1) that supports the articulated arms 42A and 42B may be attached to a large arm (not shown) that is rotatable and extensible/contractible. This large arm is operated to move the base 40 to a position in front of a selected one of the vacuum process chambers 12A to 12C or 72A to 72C. Since this structure employs no linear motor mechanism, sliding portions are reduced, thereby preventing particle generation by that much.

In the first to fifth embodiments, an explanation is given, using a semiconductor wafer W as a target substrate. The present invention is not limited to this example, and may be applied to another target substrate, such as a glass substrate for an LCD or FPD.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

1. A semiconductor processing system comprising:
a first transfer chamber formed of a casing extending in a first direction and set to be an atmospheric pressure transfer chamber;
a load-port device connected to the first transfer chamber and configured to load and unload a target substrate therethrough;
a first transfer mechanism built in the first transfer chamber and configured to hold and transfer the target substrate, the first transfer mechanism being movable in the first direction within the first transfer chamber, and comprising a transfer arm that handles the target substrate;
a second transfer chamber formed of a casing extending in a second direction perpendicular to the first direction and set to be a vacuum transfer chamber;
a load-lock chamber for pressure adjustment, connecting the first and second transfer chambers to each other and configured to provide a transfer route for the target substrate;
a second transfer mechanism built in the second transfer chamber and configured to hold and transfer the target substrate, the second transfer mechanism being movable in the second direction within the second transfer chamber, and comprising a transfer arm that handles the target substrate;
a plurality of first vacuum process chambers connected to the second transfer chamber and configured to process the target substrate in a vacuum atmosphere, the plurality of first vacuum process chambers being arrayed in the second direction along a sidewall of the second transfer chamber;
a third transfer chamber formed of a casing extending in the second direction and set to be an atmospheric pressure transfer chamber, the third transfer chamber being connected to the first transfer chamber and extending in parallel with the second transfer chamber on a side of the second transfer chamber opposite from the plurality of first vacuum process chambers;
a third transfer mechanism built in the third transfer chamber and configured to hold and transfer the target substrate, the third transfer mechanism being movable in the second direction within the third transfer chamber; and
a plurality of processing apparatuses connected to the third transfer chamber and configured to process the target substrate.

2. The system according to claim 1, wherein the third transfer mechanism comprises a transfer arm that handles the target substrate.

3. The system according to claim 2, further comprising a buffer holder disposed at a position where the first transfer chamber is connected to the third transfer chamber, and configured to temporarily place the target substrate thereon between the first and third transfer mechanisms.

4. The system according to claim 2, wherein the plurality of processing apparatuses includes a processing apparatus connected to a sidewall of the third transfer chamber opposite from the second transfer chamber.

5. The system according to claim 2, wherein the plurality of processing apparatuses includes a processing apparatus arrayed on the same side as and along with the second transfer chamber and connected to a sidewall of the third transfer chamber.

6. The system according to claim 2, further comprising a load-lock chamber for pressure adjustment, connecting the second and third transfer chambers to each other and configured to provide a transfer route for the target substrate.

7. The system according to claim 1, further comprising:
a fourth transfer chamber formed of an elongated casing and set to be an atmospheric pressure transfer chamber, the fourth transfer chamber being connected in series to an end of the third transfer chamber opposite from an end thereof connected to the first transfer chamber, and the plurality of processing apparatuses including a processing apparatus connected to the third transfer chamber through the fourth transfer chamber; and
a fourth transfer mechanism built in the fourth transfer chamber and configured to hold and transfer the target substrate, the fourth transfer mechanism being movable in a longitudinal direction of the fourth transfer chamber within the fourth transfer chamber, and comprising a transfer arm that handles the target substrate.

8. The system according to claim 7, wherein the third transfer mechanism comprises a buffer holder configured to temporarily place the target substrate thereon between the first and fourth transfer mechanisms, and is movable at a speed higher than the first, second, and fourth transfer mechanisms.

9. The system according to claim 7, wherein the casing of the fourth transfer chamber extends in the second direction, and the plurality of processing apparatuses include a processing apparatus arrayed on the same side as and along with the second transfer chamber and connected to a sidewall of the fourth transfer chamber.

10. The system according to claim 7, further comprising a load-lock chamber for pressure adjustment, connecting the second and fourth transfer chambers to each other and configured to provide a transfer route for the target substrate.

11. The system according to claim 1, further comprising:
a fourth transfer chamber formed of a casing extending in the second direction and set to be a vacuum transfer chamber, the fourth transfer chamber being connected to the first transfer chamber and extending in parallel with the third transfer chamber on a side opposite from the second transfer chamber;
a load-lock chamber for pressure adjustment, connecting the first and fourth transfer chambers to each other and configured to provide a transfer route for the target substrate;
a fourth transfer mechanism built in the fourth transfer chamber and configured to hold and transfer the target substrate, the fourth transfer mechanism being movable in the second direction within the fourth transfer chamber, and comprising a transfer arm that handles the target substrate; and
a plurality of second vacuum process chambers connected to the fourth transfer chamber and configured to process the target substrate in a vacuum atmosphere, the plurality of second vacuum process chambers being arrayed in the second direction along a sidewall of the fourth transfer chamber on a side opposite from the third transfer chamber.

12. The system according to claim 11, further comprising:
a fifth transfer chamber formed of an elongated casing and set to be an atmospheric pressure transfer chamber, the fifth transfer chamber being connected in series to an end of the third transfer chamber opposite from an end thereof connected to the first transfer chamber, and the plurality of processing apparatuses including a processing apparatus connected to the third transfer chamber through the fifth transfer chamber; and
a fifth transfer mechanism built in the fifth transfer chamber and configured to hold and transfer the target substrate, the fifth transfer mechanism being movable in a longitudinal direction of the fifth transfer chamber within the fifth transfer chamber, and comprising a transfer arm that handles the target substrate.

13. The system according to claim 12, wherein the third transfer mechanism comprises a buffer holder configured to temporarily place the target substrate thereon between the first and fifth transfer mechanisms, and is movable at a speed higher than the first, second, fourth, and fifth transfer mechanisms.

14. The system according to claim 12, wherein the casing of the fifth transfer chamber extends in the second direction, and the plurality of processing apparatuses include a processing apparatus arrayed on the same side as and along with the second transfer chamber and connected to a sidewall of the fifth transfer chamber, and a processing apparatus arrayed on the same side as and along with the fourth transfer chamber and connected to a sidewall of the fifth transfer chamber.

15. The system according to claim 12, further comprising a load-lock chamber for pressure adjustment, connecting the second and fifth transfer chambers to each other and configured to provide a transfer route for the target substrate, and a load-lock chamber for pressure adjustment, connecting the fourth and fifth transfer chambers to each other and configured to provide a transfer route for the target substrate.

16. The system according to claim 1, further comprising an alignment mechanism disposed at an end of each of the first and third transfer chambers, and configured to perform alignment of the target substrate.

17. The system according to claim 1, wherein the plurality of processing apparatuses comprise an atmospheric pressure process chamber configured to process the target substrate in an atmospheric pressure atmosphere.

18. The system according to claim 1, wherein the plurality of processing apparatuses comprise a vacuum process chamber connected to the third transfer chamber through a load-lock chamber for pressure adjustment, and configured to process the target substrate in a vacuum process chamber.

19. The system according to claim 18, wherein the plurality of first vacuum process chambers connected to the second transfer chamber comprise a plurality of process chambers arranged to perform a series of processes without exposing the target substrate to atmosphere air, and the vacuum process chamber connected to the third transfer chamber comprises a process chamber configured to perform a process that allows the target substrate to be exposed to atmosphere air after the process.

20. The system according to claim 1, further comprising a control section configured to control an operation of the system, the control section being preset to conduct:
a step of performing a series of processes on the target substrate, using the plurality of first vacuum process chambers connected to the second transfer chamber; and
a step of performing a process on the target substrate, using one of the plurality of processing apparatuses connected to the third transfer chamber, before or after the series of processes.
